(19) United States
(12) Patent Application Publication
(10) Pub. No.: US 2023/0292469 A1
(43) Pub. Date: Sep. 14, 2023

(54) LIQUID-COOLING HEAT-DISSIPATION STRUCTURE

(71) Applicant: AMULAIRE THERMAL TECHNOLOGY, INC., New Taipei City (TW)

(72) Inventors: CHING-MING YANG, New Taipei City (TW); CHENG-SHU PENG, New Taipei City (TW); TZE-YANG YEH, New Taipei City (TW)

(21) Appl. No.: 17/688,907

(22) Filed: Mar. 8, 2022

(51) Int. Cl. H05K 7/20

(52) U.S. Cl. CPC H05K 7/20409; H05K 7/20254

(57) ABSTRACT

A liquid-cooling heat-dissipation structure is provided, which includes a first structure having a plurality of skived fins and a second structure having a plurality of guide fins. The first structure and the second structure are combined to each other, so that a chamber is formed between the first structure and the second structure for receiving a working fluid, and the skived fins and the guide fins are disposed in the chamber.

### FIELD OF THE DISCLOSURE

The present disclosure relates to a heat-dissipation structure, and more particularly to a liquid-cooling heat-dissipation structure.

### BACKGROUND OF THE DISCLOSURE

Heat dissipators have been widely applied to various products. In general, high-end products usually use a water-cooling/liquid-cooling heatsink. Compared with air cooling heatsinks, the water-cooling/liquid-cooling heatsink has advantages of being quiet and providing a stable cooling performance. However, as an operating speed of heat-generating chips (such as CPU and GPU) becomes faster, the heat-dissipation performance of the conventional water-cooling heatsink still cannot satisfy heat dissipation requirements of these heat-generating chips. Thus, how to dissipate heat more efficiently by water-cooling heat dissipation technology has always been a problem to be addressed in the industry.

### SUMMARY OF THE DISCLOSURE

In response to the above-referenced technical inadequacy, the present disclosure provides a liquid-cooling heat-dissipation structure.

In one aspect, the present disclosure provides a liquid-cooling heat-dissipation structure, which includes a first structure and a second structure. The first structure has a plurality of skived fins. The second structure has a plurality of guide fins. The first structure and the second structure are combined to each other, so that a chamber is formed between the first structure and the second structure for receiving a working fluid, and the skived fins and the guide fins are disposed in the chamber.

In certain embodiments, the first structure and the second structure are combined to each other by a welding process, a friction stir welding process, a bonding process, or a locking process.

In accordance with a preferable embodiment of the present disclosure, the first structure and the second structure are each made of a metal selected from the group consisting of aluminum, copper, aluminum alloy, and copper alloy.

In certain embodiments, the first structure includes a heat-dissipating board. The heat-dissipating board has a fin surface and a contact surface that are opposite to each other, and the contact surface is configured to be in contact with a heat-generating chip. Each of the skived fins is integrally formed on the fin surface of the heat-dissipating board by a skiving process.

In certain embodiments, the second structure includes a heat-dissipating base. A recessed trough is formed on the heat-dissipating base. Each of the guide fins is integrally formed on a planar trough surface of the recessed trough. The recessed trough of the heat-dissipating base and the fin surface of the heat-dissipating board cooperatively define the chamber.

In certain embodiments, each of the skived fins has two ends. One end of the skived fin is integrally connected to the fin surface of the heat-dissipating base, and another end of the skived fin contacts or does not contact the recessed trough of the heat-dissipating base. Each of the guide fins has two ends. One end of the guide fin is integrally connected to the recessed trough of the heat-dissipating base, and another end of the guide fin contacts or does not contact the fin surface of the heat-dissipating board.

In certain embodiments, each of the skived fins has a thickness smaller than 0.3 mm.

In another aspect, the present disclosure provides a liquid-cooling heat-dissipation structure, which includes a first structure having a plurality of skived fins formed integrally by a skiving process and a second structure having a plurality of guide fins integrally formed by a metal injection molding process. The first structure and the second structure are combined to each other, so that a chamber is formed between the first structure and the second structure for receiving a working fluid, and the skived fins and the guide fins are disposed in the chamber.

In accordance with a preferable embodiment of the present disclosure, the first structure includes a heat-dissipating board. The heat-dissipating board has a fin surface and a contact surface that are opposite to each other, and the contact surface is configured to be in contact with a heat-generating chip. Each of the skived fins is integrally formed on the fin surface of the heat-dissipating board by a skiving process.

In certain embodiments, the second structure includes a heat-dissipating base, and a recessed trough is formed on the heat-dissipating base. Each of the guide fins is integrally formed on a planar trough surface of the recessed trough. The recessed trough of the heat-dissipating base and the fin surface of the heat-dissipating board cooperatively define the chamber.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a perspective exploded view of a liquid-cooling heat-dissipation structure according to the present disclosure;

FIG. 2 is an enlarged view of part II of FIG. 1;

FIG. 3 is another perspective exploded view of the liquid-cooling heat-dissipation structure according to the present disclosure;

FIG. 4 is a side view of the liquid-cooling heat-dissipation structure according to the present disclosure; and

FIG. 5 is a cross-sectional view taken along line V-V of FIG. 4.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

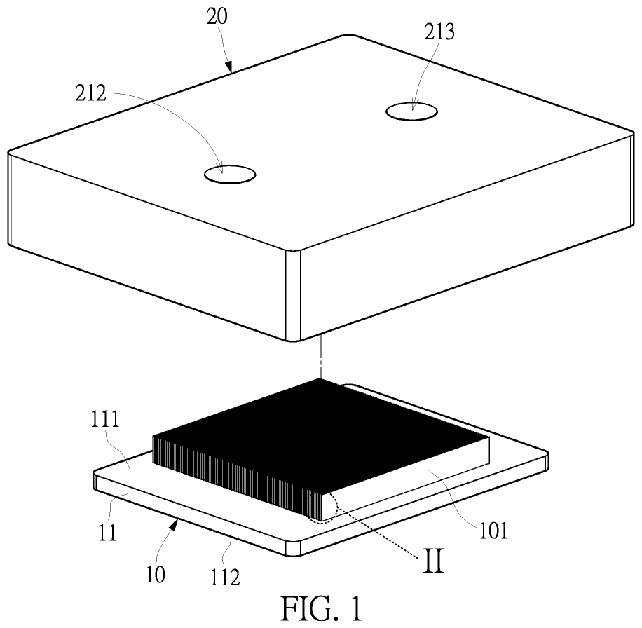

Referring to FIG. 1 to FIG. 5, an embodiment of the present disclosure provides a liquid-cooling heat-dissipation structure, which is configured to be in contact with a heat-generating chip (e.g., a CPU or a GPU). As shown in the drawings, according to one embodiment of the present disclosure, the liquid-cooling heat-dissipation structure basically includes a first structure 10 and a second structure 20 that are combined to each other. In addition, the first structure 10 and the second structure 20 can be combined to each other by, for example, a welding process, a friction stir welding (FSW) process, a bonding process, or a locking process.

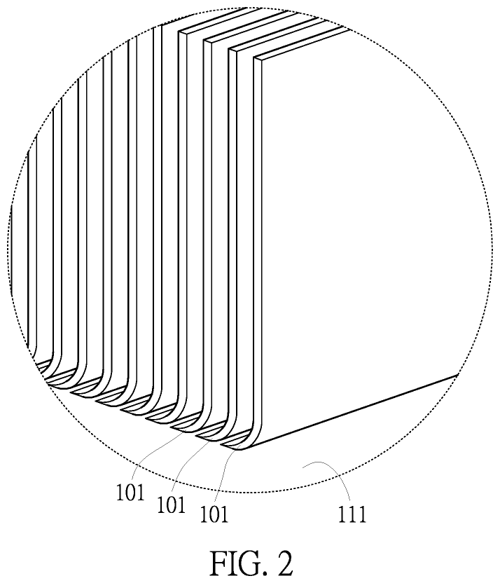

In this embodiment, the first structure 10 can be made of aluminum, copper, aluminum alloy, or copper alloy. In addition, as shown in FIGS. 1 and 2, the first structure 10 is one structural body having a plurality of skived fins 101. In detail, the first structure 10 of this embodiment includes a heat-dissipating board 11 that is in the shape of a board. However, the heat-dissipating board 11 can also be a lump or an irregularly-shaped base. In addition, the heat-dissipating board 11 has a fin surface 111 and a contact surface 112 that are opposite to each other. The contact surface 112 is used to contact the heat-generating chip. Each of the skived fins 101 is integrally formed on the fin surface 111 of the heat-dissipating board 11 by a skiving process. In other words, in this embodiment, through the skiving process, the fin surface 111 of the heat-dissipating board 11 has the skived fins 101 integrally formed thereon in an extremely dense manner Due to manufacturing characteristics of the skiving process, other specific guide fins cannot be formed on the fin surface 111 of the heat-dissipating board 11 by the skiving process.

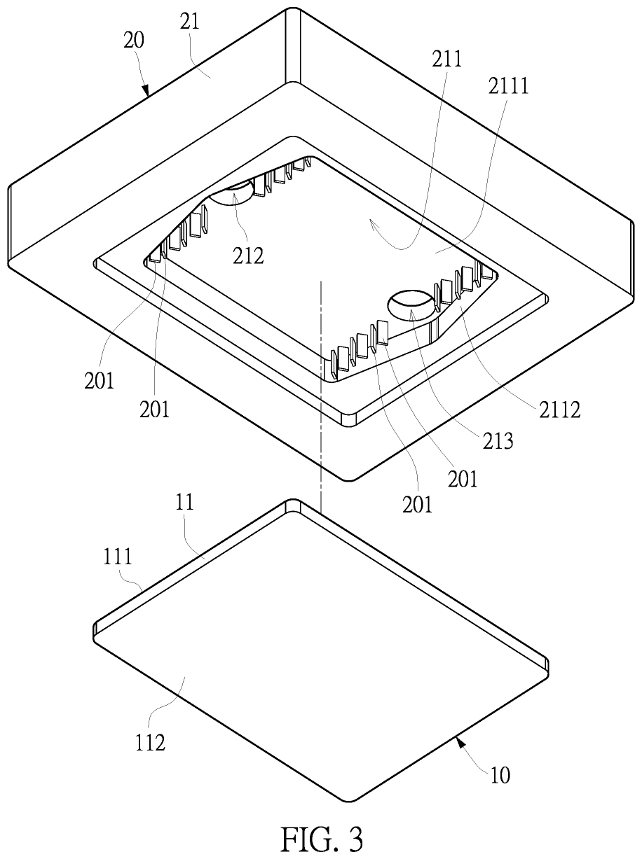

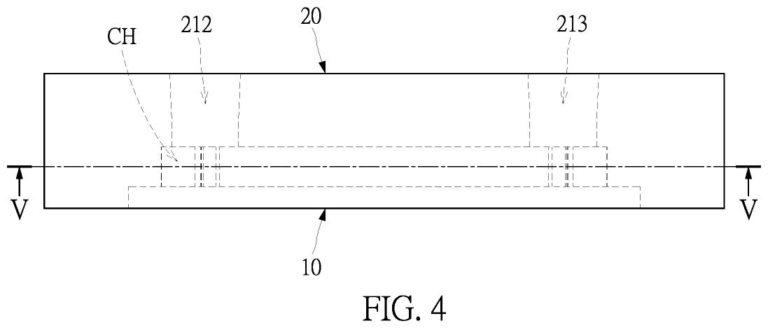

In this embodiment, the second structure 20 can be made of aluminum, copper, aluminum alloy, or copper alloy. As shown in FIG. 3, the second structure 20 is one structural body having a plurality of guide fins 201. In detail, the second structure 20 of this embodiment includes a heat-dissipating base 21. The heat-dissipating base 21 can be lump-shaped or board-shaped. In addition, the heat-dissipating base 21 further form a recessed trough 211, and each of the guide fins 201 is integrally formed on a planar trough surface 2111 of the recessed trough 211. Furthermore, the second structure 20 and the first structure are combined to each other, so that a chamber CH is formed between the first structure 10 and the second structure 20 for receiving a working fluid (as shown in FIG. 4). That is, the recessed trough 211 of the heat-dissipating base 21 of the second structure 20 and the fin surface 111 of the heat-dissipating board 11 of the first structure 10 cooperatively define the chamber CH, so that the skived fins 101 and the guide fins 201 are arranged in the chamber CH. In the present embodiment, through the first structure 10 having the skived fins 101 and the second structure 20 having the guide fins 201, and through the chamber CH being formed between the first structure 10 and the second structure 20 to receive the working fluid, the skived fins 101 and the guide fins 201 are disposed in the chamber CH. In this way, the liquid-cooling heat-dissipation structure can have an improved heat-dissipating area due to the high-density skived fins 101 that can be quickly processed, such that its heat-transferring ability is enhanced. An improved flow guiding ability can also be obtained due to the guide fins 201, such that a heat-conduction ability of the liquid-cooling heat-dissipation structure is enhanced. As a result, the heat-transferring ability and the heat-conduction ability of the liquid-cooling heat-dissipation structure can be improved simultaneously.

In addition, in this embodiment, the heat-dissipating base 21 of the second structure 20 has a first through hole 212 and a second through hole 213, each of which is in fluid communication with the recessed trough 211. The first through hole 212 can be a water inlet hole, and the second through hole 213 can be a water outlet hole. However, the present disclosure is not limited thereto. The first through hole 212 can be the water outlet hole, and the second through hole 213 can be the water inlet hole.

Moreover, the skived fins 101 of this embodiment are extremely thin and are arranged with a high density. Each of the skived fins 101 has a thickness smaller than 0.3 mm. In addition, each of the skived fins 101 has one end that is integrally connected to the fin surface 111 of the heat-dissipating board 11, and has another end that contacts or does not contact the recessed trough 211 of the heat-dissipating base 21.

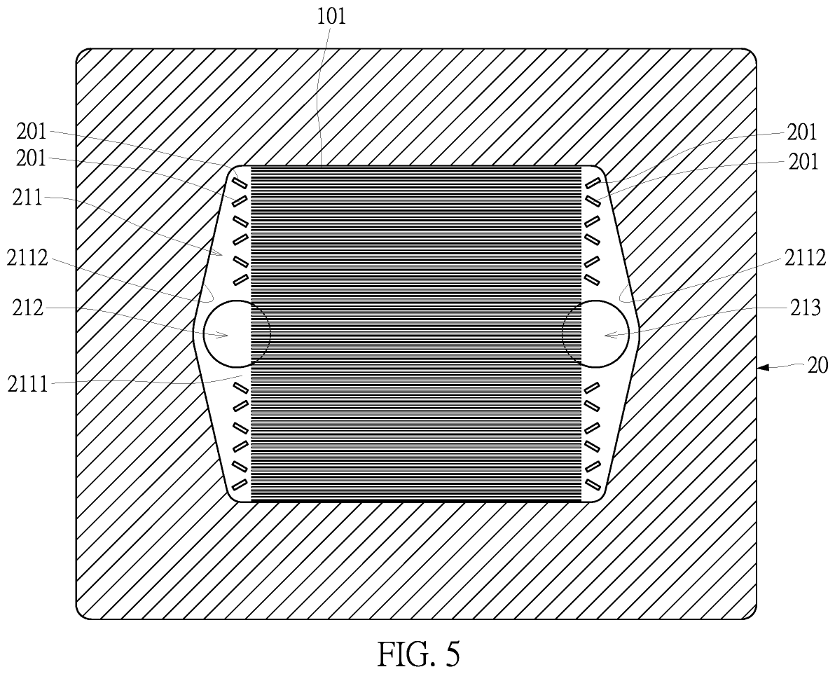

As shown in FIG. 5, the guide fins 201 of the present embodiment are located at two opposite sides of a fin structure that includes the skived fins 101. The two opposite sides of the fin structure can be the water inlet side and the water outlet side, respectively. Furthermore, two adjacent ones of the guide fins 201 can be arranged to have an included angle. Each of the guide fins 201 has one end that is integrally connected to the recessed trough 211 of the heat-dissipating base 21, and has another end that contacts or does not contact the fin surface 111 of the heat-dissipating board 11.

In this embodiment, the recessed trough 211 has the planar trough surface 2111 and two erect trough surfaces 2112 that are positioned at two opposite sides of the planar trough surface 2111. The first through hole 212 and the second through hole 213 are respectively close to concaved areas of the two erect trough surfaces 2112.

In addition, by a metal injection molding process, the second structure of this embodiment can be integrally formed to have the recessed trough 211 and the guide fins 201 that have a high accuracy and a complicated three-dimensional shape. In other words, the second structure 20 and the first structure 10 are formed by different processes, so as to satisfy different requirements of the liquid-cooling heat-dissipation structure.

### Beneficial Effects of the Embodiment

In conclusion, by virtue of a first structure having a plurality of skived fins and a second structure having a plurality of guide fins, a chamber being formed between the first structure and the second structure for receiving a working fluid, and the skived fins and the guide fins being disposed in the chamber, the liquid-cooling heat-dissipation structure provided by the present disclosure can have an improved heat-dissipating area due to the high-density skived fins that can be quickly processed, such that its heat-transferring ability is enhanced. An improved flow guiding ability can also be obtained due to the guide fins, such that the heat-conduction ability of the liquid-cooling heat-dissipation structure is enhanced. As a result, the heat-transferring ability and the heat-conduction ability of the overall structure can be improved simultaneously, thereby significantly increasing a heat dissipation efficiency of the overall structure.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A liquid-cooling heat-dissipation structure, comprising a first structure having a plurality of skived fins and a second structure having a plurality of guide fins; wherein the first structure and the second structure are combined to each other, so that a chamber is formed between the first structure and the second structure for receiving a working fluid, and the skived fins and the guide fins are disposed in the chamber.

2. The liquid-cooling heat-dissipation structure according to claim 1, wherein the first structure and the second structure are combined to each other by a welding process, a friction stir welding process, a bonding process, or a locking process.

3. The liquid-cooling heat-dissipation structure according to claim 1, wherein the first structure and the second structure are each made of a metal selected from the group consisting of aluminum, copper, aluminum alloy, and copper alloy.

4. The liquid-cooling heat-dissipation structure according to claim 1, wherein the first structure includes a heat-dissipating board, the heat-dissipating board has a fin surface and a contact surface that are opposite to each other, the contact surface is configured to be in contact with a heat-generating chip, and each of the skived fins is integrally formed on the fin surface of the heat-dissipating board by a skiving process.

5. The liquid-cooling heat-dissipation structure according to claim 4, wherein the second structure includes a heat-dissipating base, a recessed trough is formed on the heat-dissipating base, each of the guide fins is integrally formed on a planar trough surface of the recessed trough, and the recessed trough of the heat-dissipating base and the fin surface of the heat-dissipating board cooperatively define the chamber.

6. The liquid-cooling heat-dissipation structure according to claim 5, wherein each of the skived fins has two ends, one end of the skived fin is integrally connected to the fin surface of the heat-dissipating board, and another end of the skived fin contacts or does not contact the recessed trough of the heat-dissipating base; wherein each of the guide fins has two ends, one end of the guide fin is integrally connected to the recessed trough of the heat-dissipating base, and another end of the guide fin contacts or does not contact the fin surface of the heat-dissipating board.

7. The liquid-cooling heat-dissipation structure according to claim 1, wherein each of the skived fins has a thickness smaller than 0.3 mm.

8. A liquid-cooling heat-dissipation structure, comprising a first structure having a plurality of skived fins integrally formed by a skiving process and a second structure having a plurality of guide fins integrally formed by a metal injection molding process; wherein the first structure and the second structure are combined to each other, so that a chamber is formed between the first structure and the second structure for receiving a working fluid, and the skived fins and the guide fins are disposed in the chamber.

9. The liquid-cooling heat-dissipation structure according to claim 8, wherein the first structure and the second structure are combined to each other by a welding process, a friction stir welding process, a bonding process, or a locking process.

10. The liquid-cooling heat-dissipation structure according to claim 8, wherein the first structure and the second structure are each made of a metal selected from the group consisting of aluminum, copper, aluminum alloy, and copper alloy.

11. The liquid-cooling heat-dissipation structure according to claim 8, wherein the first structure includes a heat-dissipating board, the heat-dissipating board has a fin surface and a contact surface that are opposite to each other, the contact surface is configured to be in contact with a heat-generating chip, and each of the skived fins is integrally formed on the fin surface of the heat-dissipating board by the skiving process.

12. The liquid-cooling heat-dissipation structure according to claim 11, wherein the second structure includes a heat-dissipating base, a recessed trough is formed on the heat-dissipating base, each of the guide fins is integrally formed on a planar trough surface of the recessed trough by the metal injection molding process, and the recessed trough of the heat-dissipating base and the fin surface of the heat-dissipating board cooperatively define the chamber.

13. The liquid-cooling heat-dissipation structure according to claim 12, wherein each of the skived fins has two ends, one end of the skived fin is integrally connected to the fin surface of the heat-dissipating board, and another end of the skived fin contacts or does not contact the recessed trough of the heat-dissipating base; wherein each of the guide fins has two ends, one end of the guide fin is integrally connected to the recessed trough of the heat-dissipating base, and another end of the guide fin contacts or does not contact the fin surface of the heat-dissipating board.

14. The liquid-cooling heat-dissipation structure according to claim 8, wherein each of the skived fins has a thickness smaller than 0.3 mm.
